(19) United States
(12) Patent Application Publication
(10) Pub. No.: US 2012/0282067 A1
(43) Pub. Date: Nov. 8, 2012

(54) RACK-TO-RACK PACKAGED SEMICONDUCTOR DEVICE EXCHANGER

(75) Inventors: YOU MIN-CHUAN, ZHONGHE CITY (TW); HSU SHOU PING, XINDIAN CITY (TW)

(73) Assignee: TEXAS INSTRUMENTS INCORPORATED, Dallas, TX (US)

(21) Appl. No.: 13/100,038

(22) Filed: May 3, 2011

(51) Int. Cl. H01L 21/68

(52) U.S. Cl. 414/267; 414/807

(57) ABSTRACT

A rack-to-rack packaged semiconductor device exchanger has a length with a midpoint thereof, and includes an inner portion, a first outer rail and a second outer rail on opposite edges of the inner portion for accepting from opposite ends of the exchanger a first rack and a second rack configured to store packaged semiconductor devices therein. At least a first stopper has a retractable extended position which protrudes from the first outer rail for stopping the first rack or second rack from advancing past a location near the midpoint of the exchanger only from one direction. The first stopper and a second stopper can both be included.

### FIELD

Disclosed embodiments relate to rack-to-rack exchangers that transfer packaged semiconductor devices from one rack to another rack.

### BACKGROUND

Rack-to-rack packaged semiconductor device exchangers that transfer semiconductor integrated circuit devices from one rack (also called a tray, or magazine) having packaged semiconductor devices to an empty rack are commonly used for packaging, testing, visual inspection, and post test processing of packaged semiconductor devices. To help prevent angling/tilting between the racks which can cause transfer problems, it is known to use pins or a thin wall in the exchanger to stop the respective racks in the exchanger so that both racks are stopped near a midpoint along the length of the exchanger. However, these arrangements create a gap (a spacing) between the racks which during exchanging can cause package device jam problems or cracking of the packaged devices, including cracking of the plastic or cracking of the die encapsulated within the package.

### SUMMARY

Disclosed embodiments recognize that the root cause of jams and cracking of packaged devices during rack-to-rack exchanging is a gap (i.e., a spacing) and/or an angle between the racks during exchanging. If both of the respective racks (an empty rack and rack storing packaged semiconductor devices inside) are not positioned near the midpoint of the length of the package exchanger once inserted into the exchanger, one rack will have a smaller portion of its length inside the package exchanger as compared to when the rack is at or near the midpoint of the package exchanger.

For example, the packaged device containing rack may have a larger portion of its length inside the package exchanger compared to when it is at or near the midpoint, and thus will be planar (sitting flat) in the package exchanger. However, the receiving rack will have a smaller portion of its length inside the package exchanger as compared to when the rack is at or near the midpoint of the package exchanger, and will thus tend to tilt (e.g., due to gravity), and thus not sit flat in the package exchanger, so that an angular offset (tilt) is present between the respective racks at the transition area between the racks. As a result, the height of the tilted receiving rack will be higher or lower compared to the height of the packaged device containing rack during exchanging. This height differential results in bending of the packaged devices as they traverse the transition area during transfer from the packaged device containing rack to the receiving rack. The bending force experienced can be enough to cause a jam or crack packaged devices, such as cracking the encapsulating plastic, which can result in scrapped product and process stoppage.

As described herein, disclosed embodiments eliminate the gap (spacing) and/or an angle between the exchanging racks by arranging for both racks to consistently be stopped near the midpoint of the exchanger, and for both racks to sit flat during exchanging. One embodiment comprises a rack-to-rack packaged semiconductor device exchanger that has a length with a midpoint thereof, and includes an inner portion, a first outer rail and a second outer rail on opposite edges of the inner portion for accepting from opposite ends of the exchanger a first rack and a second rack configured to store packaged semiconductor devices therein. At least a first stopper has a retractable extended position which protrudes from the first outer rail for stopping the first rack or second rack from advancing past a location near the midpoint of the exchanger only from one direction.

### BRIEF DESCRIPTION OF THE DRAWINGS

FIG. 1A is a simplified depiction of an example rack-to-rack packaged semiconductor device exchanger including a first stopper and a second stopper, according to an example embodiment.

FIG. 1B is a simplified depiction of an example rack-to-rack packaged semiconductor device exchanger including a first stopper and a second stopper, according to another example embodiment.

FIG. 2 is a depiction of a portion of an example rack-to-rack packaged semiconductor device exchanger where the first stopper and second stopper are along the same outer rail and each comprise a pivotable stopper arm secured to a pivot point within a recess in the outer rail, including a compression spring between the pivotable stopper arms and the outer rail, according to another example embodiment.

FIG. 3A is a simplified three dimensional depiction of an example rack-to-rack packaged semiconductor device exchanger including a first stopper and a second stopper, according to another example embodiment.

FIG. 3B is a simplified three dimensional perspective depiction of the example rack-to-rack packaged semiconductor device exchanger shown in FIG. 3A.

FIGS. 4A-D are depictions of successive steps for an example method of exchanging packaged semiconductor devices between racks using a disclosed rack-to-rack packaged semiconductor device exchanger, according to an example embodiment.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

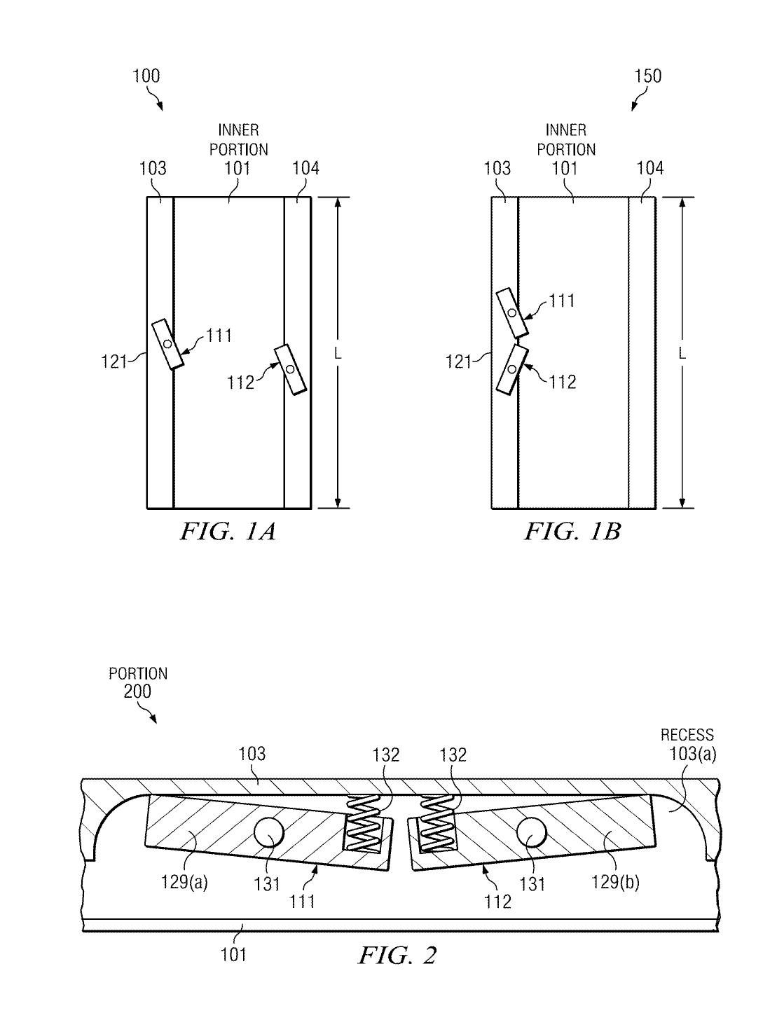

FIG. 1A is a simplified depiction of an example rack-to-rack packaged semiconductor device exchanger 100 including a first stopper 111 and a second stopper 112, according to an example embodiment. The device exchanger 100 has a length L with a midpoint thereof shown as 121. The device exchanger 100 comprises an inner portion 101, a first outer rail 103 and a second outer rail 104 on opposite edges of the inner portion 101 for accepting from opposite ends of the device exchanger 100 a first rack, and a second rack configured to store packaged semiconductor devices therein.

The first stopper 111 and second stopper 112 both provide a retractable extended position which protrude from the first outer rail 103 and second outer rail 104, respectively, for stopping a rack from advancing past a location near the midpoint 121 of the device exchanger 100 only from one direction. As used herein stopping a rack at a location “near a midpoint” of the length L of a disclosed device exchanger is defined as being in a range of locations defined by the midpoint L/2±0.05 L/2.

FIG. 1B is a simplified depiction of an example rack-to-rack packaged semiconductor device exchanger 150 including a first stopper and a second stopper, according to another example embodiment. Unlike packaged semiconductor device exchanger 100 described above, the first stopper 111 and second stopper 112 are both positioned along the same outer rail 103. Advantages to having the first stopper 111 and second stopper 112 along the same outer rail include rack-to-rack alignment in the same baseline which improves rack-to-rack entrance alignment, and not having to choose a side to begin inserting the first rack due to the stopper design symmetry so that insertion of the first rack can begin from either the left side or the right side of the exchanger 150.

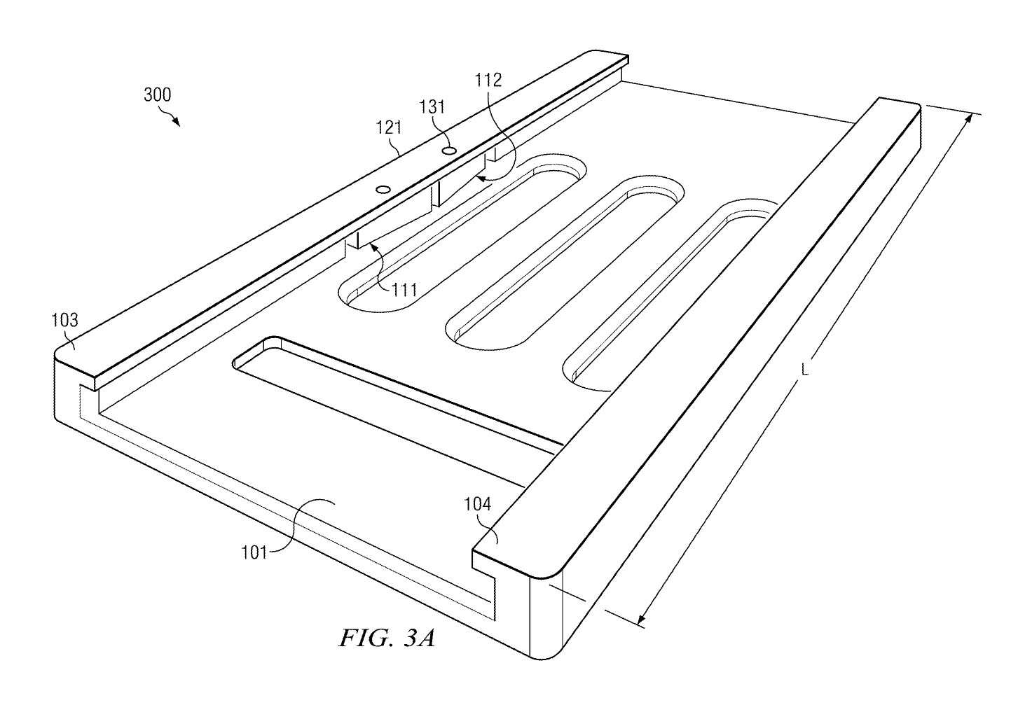

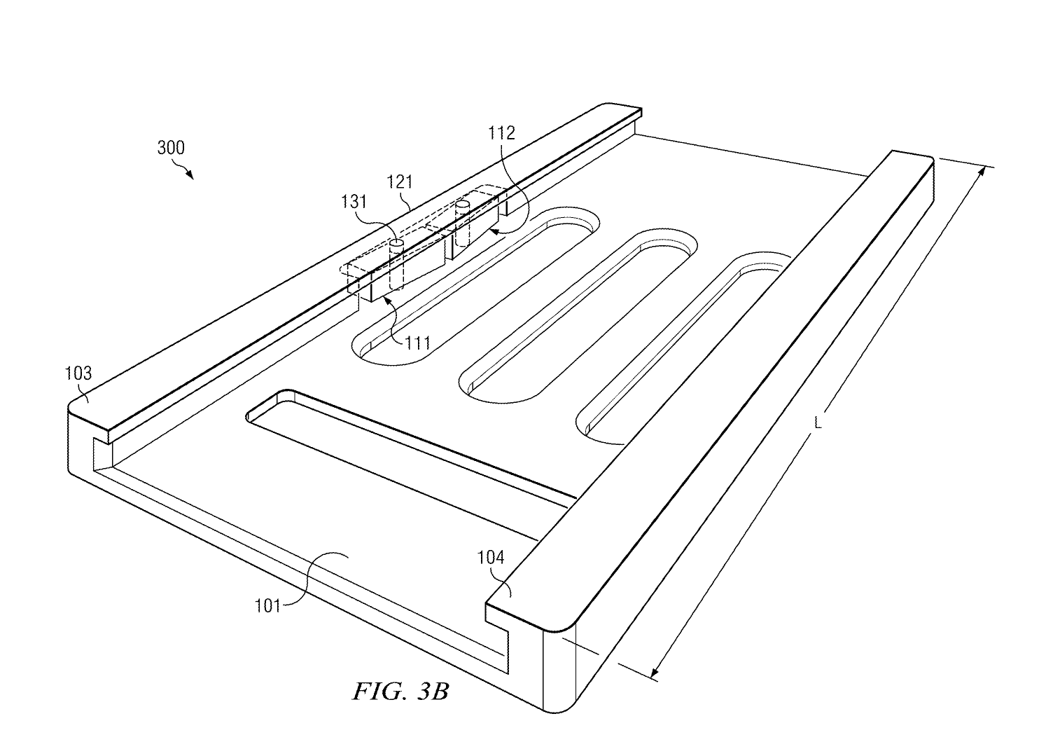

FIG. 2 is a depiction of a portion 200 of an example rack-to-rack packaged semiconductor device exchanger where the first stopper 111 and second stopper 112 are along the same outer rail 103 and each stopper 111 and 112 comprises a pivotable stopper arm 129(a) and 129(b), respectively, that are secured to a pivot point 131 within a recess 103(a) in the outer rail 103, according to an example embodiment. Compression springs 132 are shown between the pivotable stopper arms 129(a) and 129(b) and the outer rail 103. The first stopper 111 and the second stopper 112 both provide (i) a pass position that does not extend into a sliding width defined by the width of the racks as the racks slide over inner portion 101 and (ii) a retractable extended position that is retractable into the pass position wherein a portion thereof extends into the sliding width for stopping movement of the first rack or second rack. Although compression springs 132 are shown, other structures such as leaf springs can be used to allow the stoppers 111 and 112 to be moved.

FIG. 3A is a simplified three-dimensional depiction of an example rack-to-rack packaged semiconductor device exchanger 300 including a first stopper 111 and a second stopper 112 based on the rack-to-rack packaged semiconductor device exchanger 150 shown in FIG. 1B, according to another example embodiment. Both the first stopper 111 and second stopper 112 are shown in their pass positions. FIG. 3B is a simplified three dimensional perspective depiction of the example rack-to-rack packaged semiconductor device exchanger 300 shown in FIG. 3A.

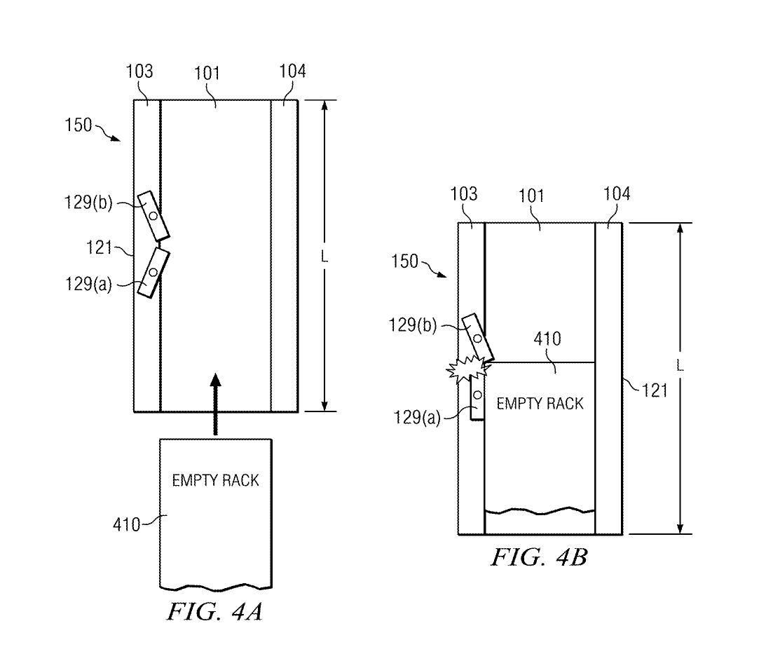

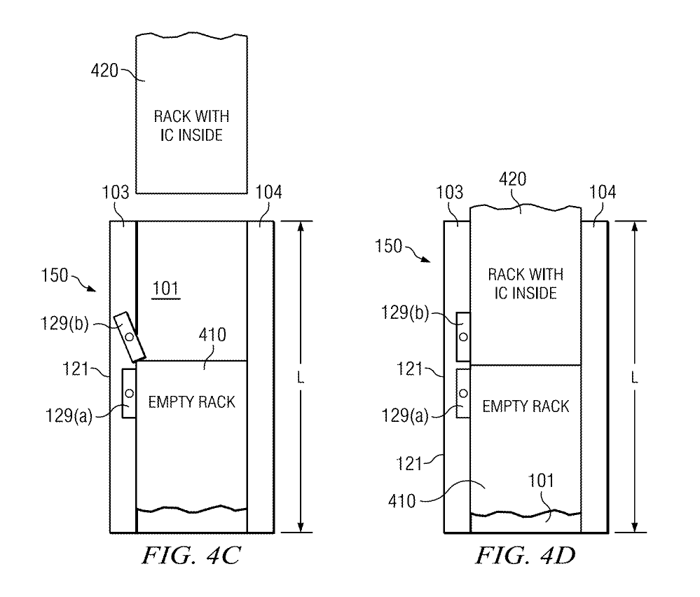

FIGS. 4A-D are depictions of successive steps for an example method of exchanging packaged semiconductor devices between racks using the example rack-to-rack packaged semiconductor device exchanger 150 shown in FIG. 1B, according to an example embodiment. FIG. 4A depicts the insertion of an empty rack 410 into one side of a disclosed rack-to-rack packaged semiconductor device exchanger. Pivotable stopper arm 129(a) and 129(b) are both shown in FIG. 4A to be in their retractable extended positions.

For manual operation, Pivotable stopper arms 129(a) and 129(b) are positioned in their extended positions by an operator of the exchanger. For automatic operation, pivotable stopper arms 129(a) and 129(b) can be moved into their extended positions without the need for operator assistance by a variety of different arrangements including actuating mechanisms and circuits modeled after those used in conventional pinball machines to the move the flipper arms.

FIG. 4B depicts the empty rack 410 reaching the midpoint 121 of the device exchanger 150 after being stopped by the first stopper arm 129(a). Due to the impact from empty rack 410, the first stopper arm 129(a) is forced into its pass position. FIG. 4C depicts a rack storing packaged semiconductor devices 420 prior to insertion. Pivotable stopper arm 129(b) is seen to be in its retractable extended position. FIG. 4D depicts the rack storing packaged semiconductor devices 420 after insertion into the device exchanger 150 after being stopped by the second stopper arm 129(b) which retracts into its pass position in response so that the rack storing packaged semiconductor devices 420 advances until it physically contacts the empty rack 410. The packaged semiconductor devices from the rack storing packaged semiconductor devices 420 can then be slid into the empty rack 410, such as under the force of gravity.

Since disclosed packaged semiconductor device exchangers such as packaged semiconductor device exchangers 100 and 150 utilize retractable stoppers as compared to conventional pins or a thin wall in the exchanger to stop the respective racks near the midpoint 121 in the exchanger, there is no gap (spacing) between the exchanging racks 410 and 420 during exchanging. Moreover, since both racks 410 and 420 are stopped near the midpoint 121, racks 410 and 420 will be aligned to one another (not angled) so that the height of the empty rack 410 for receiving will be essentially equal to the height of the rack storing packaged semiconductor devices 420, so that the packaged semiconductor devices will not be subject to bending as they traverse the transition area near midpoint 121 during transfer. Due to elimination or at least a substantial reduction in the bending force, jams or cracked packaged semiconductor devices, such as cracking of the encapsulating plastic, which can result in scrapped product and process stoppage, is eliminated or at least substantially reduced by disclosed packaged semiconductor device exchangers.

In a typical application, disclosed packaged semiconductor device exchangers exchange dual-in-line packaged semiconductor devices, such as during packaging, testing, visual inspection, and post test processing. However, disclosed packaged semiconductor device exchangers can be applied to other package types.

Disclosed packaged semiconductor device exchangers can be embodied as either manual exchangers or automatic exchangers. Automatic exchangers will generally include equipment including motors, sequencers, sensors and actuators that are operable to automatically move the pivotable stopper arm 129(a) and 129(b) into their extended positions, insert the racks into the exchanger, and provide a suitable force (e.g., a tilt to utilize gravity) to initiate the rack-to-rack transfer of the packaged semiconductor devices. Disclosed embodiments can be integrated into a variety of assembly, test and inspection flows for packaged semiconductor devices. Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

We claim:

1. A rack-to-rack packaged semiconductor device exchanger having a length with a midpoint thereof, comprising:
an inner portion, a first outer rail and a second outer rail on opposite edges of said inner portion for accepting from opposite ends of said exchanger a first rack and a second rack configured to store packaged semiconductor devices therein, and
at least a first stopper having a retractable extended position which protrudes from said first outer rail for stopping said first rack or said second rack from advancing past a location near said midpoint of said exchanger only from one direction.

2. The exchanger of claim 1, wherein:
said first rack and said second rack slide along said inner portion while occupying a sliding width on said inner portion, and
wherein said at least a first stopper comprises a first stopper and a second stopper both positioned near said midpoint of said exchanger that each provide (i) a pass position that does not extend into said sliding width and (ii) said retractable extended position that is retractable into said pass position wherein a portion thereof extends into said sliding width for stopping movement of said first rack or said second rack.

3. The exchanger of claim 2, wherein said first stopper and said second stopper are both positioned along said first outer rail or both along said second outer rail.

4. The exchanger of claim 2, further comprising a recess in at least one of said first and said second outer rails, wherein said first stopper and said second stopper are positioned within said recess.

5. The exchanger of claim 4, wherein said first stopper and said second stopper each comprise a pivotable stopper arm secured to a pivot point within said recess including a compression spring between said pivotable stopper arms and said first or said second outer side walls.

6. The exchanger of claim 1, wherein said exchanger comprises a manual exchanger.

7. A rack-to-rack packaged semiconductor device exchanger having a length with a midpoint thereof, comprising:
an inner portion, a first outer rail and a second outer rail on opposite edges of said inner portion for accepting from opposite ends of said exchanger a first rack and a second rack configured to store packaged semiconductor devices therein, and
at least a first stopper and a second stopper both positioned near said midpoint of said exchanger each having a retractable extended position which protrudes from said first outer rail for stopping said first rack or said second rack from advancing past a location near said midpoint of said exchanger only from one direction,
wherein said first rack and said second rack slide along said inner portion while occupying a sliding width on said inner portion, and
wherein said first stopper and said second stopper each provide (i) a pass position that does not extend into said sliding width and (ii) said retractable extended position that is retractable into said pass position wherein a portion thereof extends into said sliding width for stopping movement of said first rack or said second rack.

8. The exchanger of claim 7, wherein said first stopper and said second stopper are both positioned along said first outer rail or both along said second outer rail.

9. The exchanger of claim 8, further comprising a recess in at least one of said first and said second outer rails, wherein said first stopper and said second stopper are positioned within said recess, and wherein said first stopper and said second stopper each comprise a pivotable stopper arm secured to a pivot point within said recess including a compression spring between said pivotable stopper arms and said first or said second outer side walls.

10. A method of exchanging packaged semiconductor devices between racks, comprising:
inserting an empty rack into one side of a packaged semiconductor device exchanger, wherein said packaged semiconductor device exchanger includes an inner portion, a first outer rail and a second outer rail on opposite edges of said inner portion, has a length with a midpoint thereof, and includes at least one stopper that protrudes from said first outer rail to stop said empty rack from advancing past a location near said midpoint of said exchanger only from one direction;
inserting a second rack that stores packaged semiconductor devices into a second side of said packaged semiconductor device exchanger, wherein said second rack slides until said second rack contacts said empty rack, and
sliding said packaged semiconductor devices from said second rack to said empty rack.

11. The method of claim 10, wherein said at least one stopper comprises a first stopper and a second stopper both positioned near said midpoint of said packaged semiconductor device exchanger, wherein said first stopper is in a sliding path of said empty rack that stops said empty rack near said midpoint.

12. The method of claim 10, wherein said first rack and said second rack slide along said inner portion while occupying a sliding width on said inner portion, and wherein said inserting said second rack comprises inserting said second rack while said first stopper is in said sliding path, and wherein said second rack forces said first stopper out of said sliding path to allow said second rack to contact said empty rack.

13. The method of claim 10, wherein said sliding comprises using gravity.

14. The method of claim 10, wherein said packaged semiconductor devices comprise dual-in-line packaged semiconductor devices.

15. The method of claim 10, wherein said method of exchanger comprises manual exchanging.
